(19) United States
(12) Patent Application Publication
(10) Pub. No.: US 2026/0312365 A1
(43) Pub. Date: Oct. 8, 2026

(54) LASER MODULE POWER UP AND DOWN SEQUENCE

(71) Applicant: Lightmatter, Inc., Mountain View, CA (US)

(72) Inventors: Srinivasan Ashwyn Srinivasan, Toronto (CA); Erin E. Hammond, Beaverton, OR (US); Stanley W. Hsu, Cupertino, CA (US); Matthew D. Cole, South Boston, MA (US); Krishna Bharath, Portland, OR (US)

(73) Assignee: Lightmatter, Inc., Mountain View, CA (US)

(21) Appl. No.: 19/640,123

(22) Filed: Apr. 6, 2026

Related U.S. Application Data
(60) Provisional application No. 63/785,495, filed on Apr. 8, 2025.

(51) Int. Cl. H01S 5/068; H01S 5/026; H01S 5/062

(52) U.S. Cl. CPC H01S 5/06808; H01S 5/06209; H01S 5/06825; H01S 5/0261

(57) ABSTRACT

Described herein are sequences for powering up and powering down laser modules. During power-up and power-down sequences, when laser diode current is approximately zero, voltage drops across a laser supply resistance and laser diode approach zero. Under these conditions, the supply voltage from a voltage regulator may appear substantially across a laser driver pin, potentially causing permanent damage if it exceeds the maximum recommended voltage limit. A staged ramping sequence coordinates supply voltage changes with laser diode current changes to maintain driver pin voltage within acceptable limits throughout power transitions. The sequence sets supply voltage at or below the maximum limit when current is below the turn-on threshold, then increases supply voltage while raising current above the threshold.

### CROSS-REFERENCE TO RELATED APPLICATIONS

This application claims the benefit of U.S. Provisional Application Ser. No. 63/785,495, filed on Apr. 8, 2025, under Attorney Docket No. L0858.70125US00 and entitled “LASER MODULE POWER UP AND DOWN SEQUENCE,” which is hereby incorporated herein by reference in its entirety.

### BACKGROUND

Laser diodes are semiconductor devices that emit coherent light when electrical current passes through them. Unlike conventional light-emitting diodes (LEDs), laser diodes produce light through stimulated emission, resulting in a narrow, focused beam with specific wavelength characteristics. A laser diode typically includes a p-n junction or a p-i-n junction formed within a semiconductor material, where electrons and holes recombine in an active region to generate photons. The structure of a laser diode includes reflective surfaces that form an optical cavity, allowing photons to oscillate and amplify before emission. The operation of a laser diode involves several electrical parameters. A laser diode exhibits a characteristic turn-on voltage, below which minimal current flows through the device. Once the applied voltage exceeds this threshold, current begins to flow and the device transitions into its lasing regime.

Laser diodes are increasingly deployed in modern communication systems, particularly in optical interconnects and data transmission applications. The ability of laser diodes to modulate light at high frequencies makes them suitable for transmitting large amounts of data over optical fibers and through free-space optical links. As data center architectures evolve and bandwidth demands increase, laser diode-based optical communication systems are being adopted to address the limitations of traditional electrical interconnects.

### SUMMARY

In some aspects, the techniques described herein relate to a method for controlling a laser diode to emit light, the method including: controlling a voltage regulator to set a supply voltage to a first value equal to or below a maximum recommended voltage operating limit corresponding to a driver pin of a laser driver coupled to the laser diode; controlling the laser driver to increase a current flowing through the laser diode; and subsequent to the current of the laser diode exceeding a turn-on threshold associated with the laser diode, controlling the voltage regulator to increase the supply voltage to a desired setpoint while controlling the laser driver to further increase the current flowing through the laser diode, wherein the desired setpoint exceeds the maximum recommended voltage operating limit.

In some aspects, the techniques described herein relate to a method, further including: controlling the laser driver to decrease the current flowing through the laser diode; and prior to the current of the laser diode dropping below the turn-on threshold associated with the laser diode, controlling the voltage regulator to set the supply voltage to a second value equal to or below the maximum recommended voltage operating limit.

In some aspects, the techniques described herein relate to a method, further including: subsequent to controlling the voltage regulator to increase the supply voltage to a desired setpoint and prior to controlling the laser driver to decrease the current flowing through the laser diode, controlling the voltage regulator to maintain the supply voltage to the desired setpoint.

In some aspects, the techniques described herein relate to a method, wherein first value equals the second value.

In some aspects, the techniques described herein relate to a method, wherein a drive voltage appearing at the driver pin remains below the maximum recommended voltage operating limit as the voltage regulator is controlled to set the supply voltage to the first value and as the voltage regulator is controlled to increase the supply voltage to the desired setpoint.

In some aspects, the techniques described herein relate to a method, wherein the laser diode develops a voltage drop across the laser diode when the current flowing through the laser diode exceeds the turn-on threshold.

In some aspects, the techniques described herein relate to a method, wherein the voltage drop across the laser diode reduces a voltage appearing at the driver pin of the laser driver.

In some aspects, the techniques described herein relate to a method, wherein the driver pin includes a current digital-to-analog converter pin.

In some aspects, the techniques described herein relate to a method, wherein the supply voltage is provided by the voltage regulator to the laser diode through a resistance associated with a laser supply line, wherein a voltage drop across the resistance reduces a voltage appearing at the driver pin of the laser driver.

In some aspects, the techniques described herein relate to a method, wherein a resistive voltage drop across the resistance is approximately zero when the current flowing through the laser diode is approximately zero.

In some aspects, the techniques described herein relate to an apparatus, including: a laser diode; a laser driver coupled to the laser diode and configured to control a current flowing through the laser diode; a voltage regulator configured to provide a supply voltage to the laser diode; and a microcontroller coupled to the laser driver and the voltage regulator, the microcontroller configured to: control the voltage regulator to set the supply voltage to a first value equal to or below a maximum recommended voltage operating limit corresponding to a driver pin of the laser driver; control the laser driver to increase the current flowing through the laser diode; and subsequent to the current of the laser diode exceeding a turn-on threshold associated with the laser diode, control the voltage regulator to increase the supply voltage to a desired setpoint while controlling the laser driver to further increase the current flowing through the laser diode, wherein the desired setpoint exceeds the maximum recommended voltage operating limit.

In some aspects, the techniques described herein relate to an apparatus, wherein the microcontroller is further configured to: control the laser driver to decrease the current flowing through the laser diode; and prior to the current of the laser diode dropping below the turn-on threshold associated with the laser diode, control the voltage regulator to set the supply voltage to a second value equal to or below the maximum recommended voltage operating limit.

In some aspects, the techniques described herein relate to an apparatus, wherein the microcontroller is further configured to: subsequent to controlling the voltage regulator to increase the supply voltage to a desired setpoint and prior to controlling the laser driver to decrease the current flowing through the laser diode, control the voltage regulator to maintain the supply voltage at the desired setpoint.

In some aspects, the techniques described herein relate to an apparatus, wherein first value equals the second value.

In some aspects, the techniques described herein relate to an apparatus, wherein a drive voltage appearing at the driver pin remains below the maximum recommended voltage operating limit as the voltage regulator is controlled to set the supply voltage to the first value and as the voltage regulator is controlled to increase the supply voltage to the desired setpoint.

In some aspects, the techniques described herein relate to an apparatus, wherein the laser diode develops a voltage drop across the laser diode when the current flowing through the laser diode exceeds the turn-on threshold.

In some aspects, the techniques described herein relate to an apparatus, wherein the voltage drop across the laser diode reduces a voltage appearing at the driver pin of the laser driver.

In some aspects, the techniques described herein relate to an apparatus, wherein the driver pin includes a current digital-to-analog converter pin.

In some aspects, the techniques described herein relate to an apparatus, wherein the supply voltage is provided by the voltage regulator to the laser diode through a resistance associated with a laser supply line, wherein a voltage drop across the resistance reduces a voltage appearing at the driver pin of the laser driver.

In some aspects, the techniques described herein relate to an apparatus, wherein a resistive voltage drop across the resistance is approximately zero when the current flowing through the laser diode is approximately zero.

The foregoing general description of the illustrative embodiments and the following detailed description thereof are merely exemplary aspects of the teachings of this disclosure and are not restrictive.

### BRIEF DESCRIPTION OF FIGURES

Various aspects and embodiments of the application will be described with reference to the following figures. It should be appreciated that the figures are not necessarily drawn to scale. Items appearing in multiple figures are indicated by the same reference number in the figures in which they appear.

FIG. 1A illustrates a schematic block diagram of a system for controlling a laser diode, according to aspects of the present disclosure.

FIG. 1B illustrates a current-voltage characteristic curve of a laser diode, according to aspects of the present disclosure.

FIG. 2 illustrates a plot of a sequence for powering up and powering down a laser diode, according to aspects of the present disclosure.

FIG. 3 illustrates a plot of a staged sequence for powering up and powering down the laser diode of FIG. 2, according to aspects of the present disclosure.

### DETAILED DESCRIPTION

Laser diode driver integrated circuits (ICs) may include a driver (e.g., a digital-to-analog converter (DAC)) pin that drives a laser diode with current to emit light. The driver pin may have a maximum recommended operating voltage limit (V_{max,op,dac}) that corresponds to an analog supply voltage (Vₐₙₐ) provided to the laser diode driver IC. A voltage overhead (V_{dac,ov}) across the driver pin may be present to deliver a required laser diode current (I_{ld}).

During normal operation of a laser diode, a supply voltage (Vₗₐₛₑᵣ) from a voltage regulator may be distributed across multiple voltage drops within the circuit. The supply voltage may equal the sum of a voltage drop across the laser diode (V_{ld}), a voltage drop due to current flowing through a resistance associated with the laser supply (V_{ir,laser}), and the voltage overhead across the driver pin (V_{dac,ov}). When the laser diode conducts current, these voltage drops share the supply voltage such that the voltage appearing at the driver pin remains within acceptable limits.

However, the inventors have recognized and appreciated that, during power-up and power-down sequences, the laser diode current (I_{ld}) may be approximately zero. When the laser diode current is zero, the voltage drop due to current flowing through the laser supply resistance (V_{ir,laser}) becomes zero. Additionally, when the laser diode current is below a turn-on threshold of the laser diode, the voltage drop across the laser diode (Vid) also approaches zero. Under these conditions, the supply voltage (Vₗₐₛₑᵣ) may appear substantially across the driver pin of the laser diode driver IC.

If the supply voltage (Vₗₐₛₑᵣ) exceeds the maximum recommended operating voltage limit (V_{max,op,dac}) of the driver pin during these power-up or power-down conditions, the laser diode driver IC may suffer permanent irreversible damage. This situation presents a challenge when operating a voltage regulator at supply voltage levels that exceed the maximum recommended operating limit of the laser diode driver IC, as may be desirable to accommodate various laser diode technologies with different operating voltage requirements. Conventional approaches may address this challenge by designing laser diode driver ICs that are uniquely compatible with specific laser diode technologies, which may limit flexibility in mixing and matching laser diode driver ICs with different laser diode technologies.

Recognizing these challenges, the inventors have developed a staged ramping sequence for the supply voltage (Vₗₐₛₑᵣ) coordinated with the laser diode current (I_{ld}) to protect the laser diode driver IC during power-up and power-down operations. The staged ramping sequence may be implemented as a software-defined solution executed by a microcontroller. The microcontroller may control both a voltage regulator that provides the supply voltage and the laser diode driver IC that controls the laser diode current, coordinating the timing and magnitude of changes to both parameters according to a predetermined sequence.

The software-defined staged ramping sequence described herein may allow mixing and matching different laser-diode driver ICs with different laser-diode technologies without compromising driver IC specifications. By controlling the relationship between the supply voltage and the laser diode current during transient conditions, the sequence may enable operation of the voltage regulator at supply voltage levels that exceed the maximum recommended operating limit of the laser diode driver IC during steady-state operation, while maintaining the voltage at the driver pin within safe limits during power-up and power-down transitions. This approach may provide flexibility in selecting laser diode driver ICs and laser diode technologies based on other performance specifications rather than being constrained by voltage compatibility requirements.

The staged ramping sequence may exploit the nonlinear voltage characteristic of the laser diode, in which the laser current experiences a significant increase only after the laser voltage has exceeded the turn-on threshold voltage. When the laser diode current exceeds the turn-on threshold of the laser diode, the laser diode begins to conduct and develops a voltage drop across the laser diode. This voltage drop across the laser diode reduces the voltage appearing at the driver pin of the laser diode driver IC. By coordinating increases in the supply voltage with increases in the laser diode current that cause the laser diode to conduct, the sequence may maintain the voltage at the driver pin below the maximum recommended operating voltage limit throughout the power-up and power-down transitions.

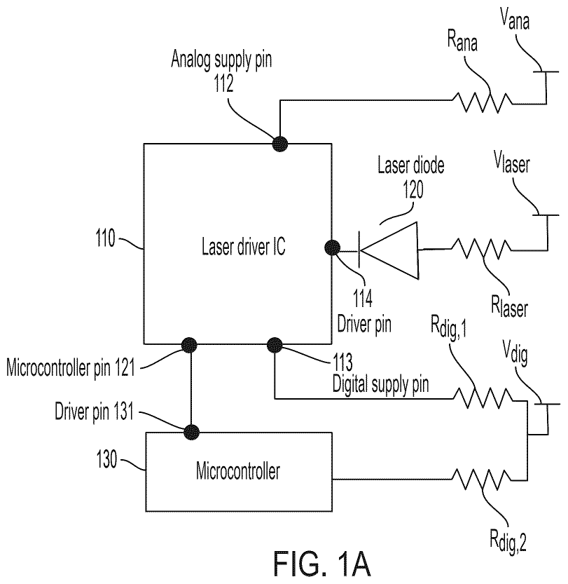

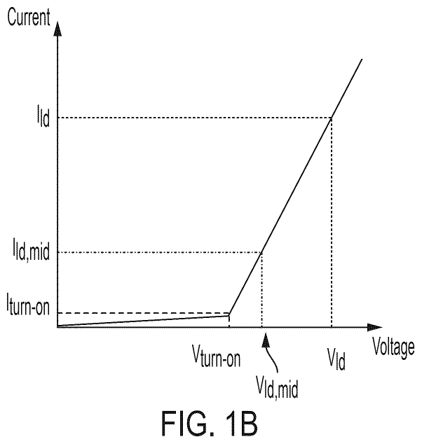

Referring to FIG. 1A, a system for controlling a laser diode includes a laser driver IC 110, a laser diode 120, and a microcontroller 130. The laser driver IC 110 may be coupled to the laser diode 120 to control current flowing through the laser diode 120 to emit light. The microcontroller 130 may be coupled to the laser driver IC 110 to provide control signals that determine the operating parameters of the laser driver IC 110. Laser diode 120 may be a distributed feedback laser (DFB), a ring laser, a frequency comb laser, a quantum dot laser, a vertical cavity surface emitting laser (VCSEL), a fiber laser, etc.

The system may include three separate voltage regulators providing distinct supply voltages to different components of the system. A first voltage regulator may provide a supply voltage Vₗₐₛₑᵣ for the laser diode 120. A second voltage regulator may provide a supply voltage Vₐₙₐ for an analog supply pin 112 of the laser driver IC 110. A third voltage regulator may provide a supply voltage V_{dig} for a digital supply pin 113 of the laser driver IC 110 and for the microcontroller 130. This arrangement of separate voltage regulators may allow independent control of the voltage levels supplied to the analog, digital, and laser supply domains within the system.

With continued reference to FIG. 1A, the system may include resistance elements associated with the voltage supply lines. A resistance Rₗₐₛₑᵣ may be associated with the supply line providing Vₗₐₛₑᵣ to the laser diode 120. As described in detail further below, when current flows through the resistance Rₗₐₛₑᵣ, a voltage drop across the resistance reduces a portion of the supply voltage appearing at the driver pin 114. A resistance Rₐₙₐ may be associated with the supply line providing Vₐₙₐ to the analog supply pin 112 of the laser driver IC 110. A resistance R_{dig,1} may be associated with the supply line providing V_{dig} to the digital supply pin 113 of the laser driver IC 110. A resistance R_{dig,2} may be associated with the supply line providing V_{dig} to the microcontroller 130. These resistance elements may represent resistive voltage drops in the respective supply lines.

The laser driver IC 110 may communicate with the microcontroller 130 through a serial peripheral interface (SPI), for example. As further shown in FIG. 1A, a microcontroller pin 121 of the laser driver IC 110 may be coupled to a driver pin 131 of the microcontroller 130 to establish the SPI communication interface. The SPI communication interface may allow the microcontroller 130 to transmit control commands to the laser driver IC 110 and to receive status information from the laser driver IC 110. Through this communication interface, the microcontroller 130 may control the laser diode current provided by the laser driver IC 110 to the laser diode 120.

The laser driver IC 110 may include a driver pin 114 that provides current to the laser diode 120 to cause the laser diode to emit light. The driver pin 114 may represent the output of a current digital-to-analog converter (or other types of drivers) within the laser driver IC 110 that converts digital control signals from the microcontroller 130 into an analog current for driving the laser diode 120. The voltage appearing at the driver pin 114 may be constrained by the maximum recommended operating voltage limit (V_{max,op,dac}) of the laser driver IC 110. During normal operation when the laser diode 120 conducts current, the voltage at the driver pin 114 may remain within acceptable limits. However, during power-up and power-down conditions when the laser diode current is approximately zero, the voltage at the driver pin 114 may approach the supply voltage (Vₗₐₛₑᵣ), potentially exceeding the maximum recommended operating voltage limit.

Referring to FIG. 1B, a current-voltage characteristic curve of the laser diode 120 illustrates the relationship between the voltage drop across the laser diode (V_{ld}) and the current flowing through the laser diode (I_{ld}). The characteristic curve exhibits a nonlinear behavior that reflects the turn-on voltage characteristic of the laser diode 120.

When the laser diode current (I_{ld}) is zero, the voltage drop across the laser diode (V_{ld}) may be approximately zero. As shown in FIG. 1B, the characteristic curve remains near zero current until the applied voltage reaches a turn-on voltage (Vₜᵤᵣₙ₋ₒₙ). Below the turn-on voltage, the laser diode 120 does not conduct appreciable current, and the voltage drop across the laser diode 120 remains negligible.

Once the applied voltage exceeds the turn-on threshold (Vₜᵤᵣₙ₋ₒₙ), current begins to flow through the laser diode 120. At the turn-on threshold, the current equals a turn-on current (Iₜᵤᵣₙ₋ₒₙ) and the voltage equals the turn-on voltage (Vₜᵤᵣₙ₋ₒₙ). Beyond the turn-on threshold, the current through the laser diode 120 increases in a substantially linear manner with increasing voltage. The characteristic curve shows that at an intermediate operating condition, the current may equal I_{ld,mid} and the voltage may equal V_{ld,mid}.

The nonlinear voltage characteristic of the laser diode 120 may be exploited in the staged ramping sequence. Because the voltage drop across the laser diode (V_{ld}) is approximately zero when the laser diode current (I_{ld}) is zero or below the turn-on threshold, the supply voltage (Vₗₐₛₑᵣ) may appear substantially across the driver pin of the laser driver IC 110 during these conditions. By coordinating increases in the supply voltage with increases in the laser diode current that cause the laser diode 120 to conduct and develop a voltage drop, the staged ramping sequence may maintain the voltage at the driver pin within acceptable limits.

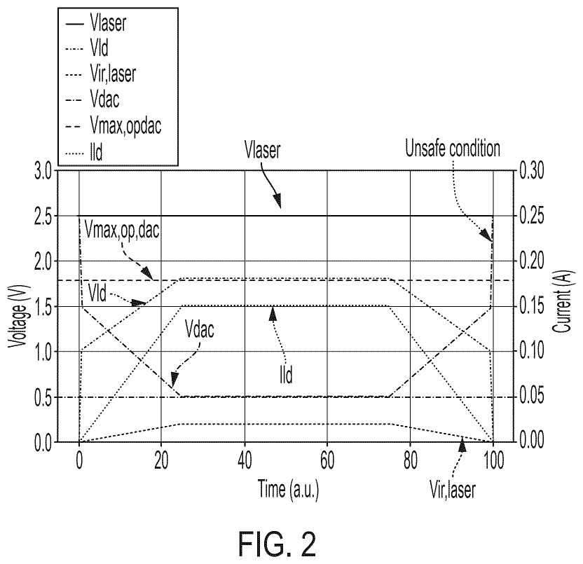

Referring to FIG. 2, a plot illustrates a sequence for powering up and powering down a laser diode that demonstrates the risk of damage to a laser diode driver IC. The x-axis represents time in arbitrary units ranging from 0 to 100. The left y-axis represents voltage expressed in volts ranging from 0.0 to 3.0 V, and the right y-axis represents current expressed in amperes ranging from 0.00 to 0.30 A. The power-up sequence begins at time t=0 and ends at approximately t=25. The power-down sequence begins at approximately t=75 and ends at t=100. The steady-state operation period extends from approximately t=25 to approximately t=75, during which the laser diode current and supply voltage remain at their operating levels.

During operation of the laser diode, the supply voltage (Vₗₐₛₑᵣ) from the voltage regulator may be distributed across multiple voltage drops within the circuit according to the following relationship:

$${V}_{laser} = {V}_{l d} + {V}_{ir , laser} + {V}_{dac , ov}$$

In this relationship, V_{ld} represents the voltage drop across the laser diode, V_{ir,laser} represents the resistive (IR) voltage drop due to current flowing through the laser supply resistance, and V_{dac,ov} represents the voltage overhead across the driver pin 114. The IR drop voltage (V_{ir,laser}) equals the product of the laser supply resistance (Rₗₐₛₑᵣ) and the laser diode current (I_{ld}), expressed as:

$${V}_{ir , laser} = {R}_{laser} \times {I}_{l d}$$

As shown in FIG. 2, during steady-state operation when the laser diode current (I_{ld}) is at the operating level of approximately 0.15 A, the supply voltage (Vₗₐₛₑᵣ) remains at approximately 2.5 V. Under these conditions, the voltage drop across the laser diode (Via), the IR drop voltage (V_{ir,laser}), and the voltage overhead across the driver pin (V_{dac}) share the supply voltage such that the voltage appearing at the drive pin 114 remains within acceptable limits below the maximum recommended operating limit (V_{max,op,dac}) of approximately 1.8 V.

With continued reference to FIG. 2, during the power-up sequence beginning at t=0 and during the power-down sequence ending at approximately t=100, the laser diode current (I_{ld}) may be approximately zero. When the laser diode current is zero, the IR drop voltage (V_{ir,laser}) becomes zero because V_{ir,laser} equals the product of the laser supply resistance and the laser diode current. Additionally, when the laser diode current is below the turn-on threshold of the laser diode, the voltage drop across the laser diode (V_{ld}) also approaches zero.

Under these conditions where I_{ld}, V_{ir,laser}, and V_{ld} are approximately zero, the circuit runs the risk of having the supply voltage (Vₗₐₛₑᵣ) appear substantially across the drive pin 114 of the laser diode driver IC. If the supply voltage exceeds the maximum recommended operating limit at the driver pin (V_{max,op,dac}) during these power-up or power-down conditions, the laser diode driver IC may suffer permanent irreversible damage. As illustrated in FIG. 2, when the supply voltage (Vₗₐₛₑᵣ) is set to the operating level of approximately 2.5 V while the laser diode current remains at or near zero, the voltage at the driver pin 114 (V_{dac}) may exceed the maximum recommended operating limit (V_{max,op,dac}) of approximately 1.8 V, creating the risk of damage to the laser diode driver IC. In FIG. 2, this occurs between approximately t=0 and t=1 and again between t=99 and t=100.

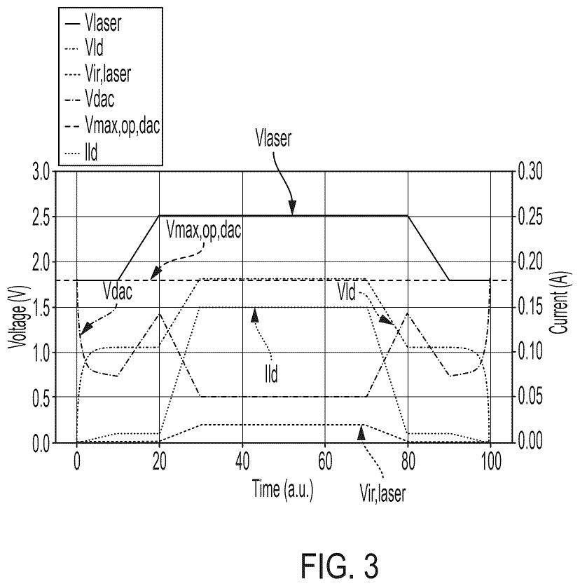

Referring to FIG. 3, a plot illustrates a staged ramping sequence for powering up and powering down a laser diode that protects the laser diode driver IC from damage. FIG. 3 is similar to FIG. 2 in that the x-axis represents time in arbitrary units ranging from 0 to 100; the left y-axis represents voltage expressed in volts ranging from 0.0 to 3.0 V, and the right y-axis represents current expressed in amperes ranging from 0.00 to 0.30 A. The staged ramping sequence of FIG. 3 coordinates changes in the supply voltage (Vₗₐₛₑᵣ) with changes in the laser diode current (I_{ld}) to maintain the voltage at the driver pin 114 within acceptable limits throughout the power-up and power-down transitions. The staged ramping sequence exploits the nonlinear voltage characteristic of the laser diode, in which the laser diode current experiences a significant increase only after the laser diode voltage has exceeded the turn-on threshold voltage. As illustrated in FIG. 3, the supply voltage (Vₗₐₛₑᵣ) is increased to the desired setpoint subsequent to the laser diode current (I_{ld}) exceeding the turn-on threshold associated with the laser diode (at about t=20).

The staged ramping sequence may include at least four distinct stages that coordinate the supply voltage and the laser diode current. A first stage (Stage-1) may begin the power-up sequence. A second stage (Stage-2) may complete the power-up sequence and transition to steady-state operation. A third stage (Stage-3) may begin the power-down sequence. A fourth stage (Stage-4) may complete the power-down sequence.

In Stage-1, microcontroller 130 may first control a voltage regulator to set the supply voltage (Vₗₐₛₑᵣ) to a first value equal to or below the maximum recommended operating voltage limit (V_{max,op,dac}) of the driver pin 114. In this example, the voltage regulator sets Vₗₐₛₑᵣ to be equal to V_{max,op,dac} (about 1.8V). As shown in FIG. 3, Stage-1 begins at approximately t=0. By setting the supply voltage to the first value rather than the final operating setpoint, the microcontroller 130 may avoid damage to the laser diode driver IC when the laser diode current is zero or below the turn-on threshold. After setting the supply voltage to the first value, the microcontroller 130 may then control the laser diode driver IC to increase the current flowing through the laser diode (I_{ld}) until the current crosses the turn-on threshold (Iₜᵤᵣₙ₋ₒₙ) associated with the laser diode. Once the laser diode current exceeds the turn-on threshold, the laser diode begins to conduct and develops a voltage drop across the laser diode (Via), which reduces the voltage appearing at the driver pin 114 (V_{dac}).

With continued reference to FIG. 3, in Stage-2, microcontroller 130 may control the voltage regulator to ramp the supply voltage (Vₗₐₛₑᵣ) up to a desired setpoint. In the example of FIG. 3, the desired setpoint is approximately 2.5 V. The desired setpoint exceeds the maximum recommended operating voltage limit (V_{max,op,dac}). To ensure that the voltage appearing at the driver pin 114 (V_{dac}) remains below the maximum recommended operating voltage limit (V_{max,op,dac}), the microcontroller 130 controls the voltage regulator to ramp the supply voltage (Vₗₐₛₑᵣ) up to the desired setpoint subsequent to the laser diode current (I_{ld}) exceeding the turn-on threshold. Stage-2 begins at approximately t=20 in the illustrated example. During Stage-2, microcontroller 130 may control the laser diode driver IC to further increase the laser diode current (I_{ld}) in parallel with the increase in the supply voltage. Because the laser diode current has already exceeded the turn-on threshold, the laser diode conducts current and develops a voltage drop (V_{ld}) that shares the supply voltage with the voltage at the driver pin 114. As the supply voltage increases during Stage-2, the corresponding increase in the laser diode current causes the voltage drop across the laser diode (V_{ld}) and the voltage drop across the resistance (V_{ir,laser}) to increase proportionally. Together, the voltage drop across the laser diode and the voltage drop across the resistance reduce the voltage appearing at the driver pin 114, maintaining the voltage at the driver pin below the maximum recommended operating voltage limit.

Following Stage-2, the system may operate in a steady-state condition from approximately t=20 to approximately t=80, during which the supply voltage (Vₗₐₛₑᵣ) remains at the desired setpoint of approximately 2.5 V and the laser diode current (I_{ld}) remains at the operating level of approximately 0.15 A.

In Stage-3, microcontroller 130 may control the voltage regulator to ramp the supply voltage (Vₗₐₛₑᵣ) down from the desired setpoint toward the maximum recommended operating voltage limit (V_{max,op,dac}). As shown in FIG. 3, Stage-3 begins at approximately t=80. During Stage-3, microcontroller 130 may control the laser diode driver IC to decrease the laser diode current (I_{ld}) in parallel with the decrease in the supply voltage. The controller may continue decreasing the laser diode current until the current drops below the turn-on threshold (Iₜᵤᵣₙ₋ₒₙ) associated with the laser diode. By coordinating the decrease in the supply voltage with the decrease in the laser diode current, the staged ramping sequence may maintain the voltage at the driver pin 114 below the maximum recommended operating voltage limit throughout Stage-3.

In Stage-4, microcontroller 130 may control the voltage regulator to set the supply voltage (Vₗₐₛₑᵣ) to a second value equal to or below the maximum recommended operating voltage limit (V_{max,op,dac}). To ensure that the voltage appearing at the driver pin 114 (V_{dac}) remains below the maximum recommended operating voltage limit (V_{max,op,dac}), the microcontroller 130 controls the voltage regulator to ramp the supply voltage (Vₗₐₛₑᵣ) down prior to the laser diode current (I_{ld}) dropping below the turn-on threshold. As shown in FIG. 3, Stage-4 begins at approximately t=90. During Stage-4, microcontroller 130 may control the laser diode driver IC to ramp the laser diode current (I_{ld}) further down toward zero. Because the supply voltage is maintained at or below the maximum recommended operating voltage limit during Stage-4, the voltage at the driver pin 114 remains within acceptable limits even as the laser diode current decreases below the turn-on threshold and the voltage drop across the laser diode approaches zero.

The staged ramping approach illustrated in FIG. 3 may ensure that the supply voltage (Vₗₐₛₑᵣ) does not exceed the maximum recommended operating voltage limit (V_{max,op,dac}) when the laser diode current (I_{ld}) is below the turn-on threshold. During Stage-1, when the laser diode current is at or below the turn-on threshold and the voltage drop across the laser diode is approximately zero, the supply voltage is constrained to the first value equal to or below the maximum recommended operating voltage limit. During Stage-4, when the laser diode current decreases below the turn-on threshold, the supply voltage is constrained to the second value equal to or below the maximum recommended operating voltage limit. In some embodiments, the first value may equal the second value; in other embodiments, they may be different values. During Stage-2 and Stage-3, when the supply voltage exceeds the maximum recommended operating voltage limit, the laser diode current is above the turn-on threshold such that the laser diode conducts and develops a voltage drop that reduces the voltage appearing at the driver pin. This coordination between the supply voltage and the laser diode current may protect the laser diode driver IC from damage throughout the power-up and power-down transitions.

Various methods may be used to determine when the laser diode current has exceeded the turn-on threshold. In some embodiments, open loop timing may be used, in which the microcontroller 130 uses timers to control the voltage regulator to increase the supply voltage after a predetermined time interval has elapsed from commanding the laser driver to increase current. In some embodiments, open loop hardware-based control with filters may be used, in which the microcontroller 130 controls the voltage regulator to increase voltage which is then delivered through a passive filter power delivery network including resistive-inductive-capacitive (RLC) elements to slow down the ramp rate of the supply voltage. In some embodiments, open loop or closed loop digital stepping may be used, in which the microcontroller 130 uses timers and a digital control interface (e.g., I2C) to a voltage regulator module (VRM) to perform quantized steps of the supply voltage. In some embodiments, closed loop control may be used, in which the microcontroller 130 monitors laser driver output currents and laser diode voltages to determine when the laser diode current has exceeded the turn-on threshold before increasing the supply voltage to the desired setpoint.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

As used herein, terms such as “above,” “below,” “over,” “under,” “adjacent,” “upper,” “top,” “lower,” “bottom,” “vertical,” “horizontal,” “lateral,” and similar positional or directional descriptors are used solely to describe the relative arrangement and orientation of features as illustrated in the drawings and are not intended to be limiting. Such terms do not require any particular orientation of the device in use, manufacture, or operation, and the described features may be oriented in any direction without departing from the scope of the present disclosure. Moreover, these terms are not intended to imply any absolute position, gravitational reference, or fixed spatial relationship, and components described as being positioned using positional or directional descriptors may be arranged in different relative positions, including inverted, rotated, or otherwise reoriented configurations, while still performing the same function in substantially the same way to achieve substantially the same result.

What is claimed is:

1. A method for controlling a laser diode to emit light, the method comprising:
controlling a voltage regulator to set a supply voltage to a first value equal to or below a maximum recommended voltage operating limit corresponding to a driver pin of a laser driver coupled to the laser diode;
controlling the laser driver to increase a current flowing through the laser diode; and
subsequent to the current of the laser diode exceeding a turn-on threshold associated with the laser diode, controlling the voltage regulator to increase the supply voltage to a desired setpoint while controlling the laser driver to further increase the current flowing through the laser diode, wherein the desired setpoint exceeds the maximum recommended voltage operating limit.

2. The method of claim 1, further comprising:
controlling the laser driver to decrease the current flowing through the laser diode; and
prior to the current of the laser diode dropping below the turn-on threshold associated with the laser diode, controlling the voltage regulator to set the supply voltage to a second value equal to or below the maximum recommended voltage operating limit.

3. The method of claim 2, further comprising:
subsequent to controlling the voltage regulator to increase the supply voltage to a desired setpoint and prior to controlling the laser driver to decrease the current flowing through the laser diode, controlling the voltage regulator to maintain the supply voltage to the desired setpoint.

4. The method of claim 2, wherein first value equals the second value.

5. The method of claim 1, wherein a drive voltage appearing at the driver pin remains below the maximum recommended voltage operating limit as the voltage regulator is controlled to set the supply voltage to the first value and as the voltage regulator is controlled to increase the supply voltage to the desired setpoint.

6. The method of claim 1, wherein the laser diode develops a voltage drop across the laser diode when the current flowing through the laser diode exceeds the turn-on threshold.

7. The method of claim 6, wherein the voltage drop across the laser diode reduces a voltage appearing at the driver pin of the laser driver.

8. The method of claim 1, wherein the driver pin comprises a current digital-to-analog converter pin.

9. The method of claim 1, wherein the supply voltage is provided by the voltage regulator to the laser diode through a resistance associated with a laser supply line, wherein a voltage drop across the resistance reduces a voltage appearing at the driver pin of the laser driver.

10. The method of claim 9, wherein a resistive voltage drop across the resistance is approximately zero when the current flowing through the laser diode is approximately zero.

11. An apparatus, comprising:
a laser diode;
a laser driver coupled to the laser diode and configured to control a current flowing through the laser diode;
a voltage regulator configured to provide a supply voltage to the laser diode; and
a microcontroller coupled to the laser driver and the voltage regulator, the microcontroller configured to:
control the voltage regulator to set the supply voltage to a first value equal to or below a maximum recommended voltage operating limit corresponding to a driver pin of the laser driver;
control the laser driver to increase the current flowing through the laser diode; and
subsequent to the current of the laser diode exceeding a turn-on threshold associated with the laser diode, control the voltage regulator to increase the supply voltage to a desired setpoint while controlling the laser driver to further increase the current flowing through the laser diode, wherein the desired setpoint exceeds the maximum recommended voltage operating limit.

12. The apparatus of claim 11, wherein the microcontroller is further configured to:
control the laser driver to decrease the current flowing through the laser diode; and
prior to the current of the laser diode dropping below the turn-on threshold associated with the laser diode, control the voltage regulator to set the supply voltage to a second value equal to or below the maximum recommended voltage operating limit.

13. The apparatus of claim 12, wherein the microcontroller is further configured to:
subsequent to controlling the voltage regulator to increase the supply voltage to a desired setpoint and prior to controlling the laser driver to decrease the current flowing through the laser diode, control the voltage regulator to maintain the supply voltage at the desired setpoint.

14. The apparatus of claim 12, wherein first value equals the second value.

15. The apparatus of claim 11, wherein a drive voltage appearing at the driver pin remains below the maximum recommended voltage operating limit as the voltage regulator is controlled to set the supply voltage to the first value and as the voltage regulator is controlled to increase the supply voltage to the desired setpoint.

16. The apparatus of claim 11, wherein the laser diode develops a voltage drop across the laser diode when the current flowing through the laser diode exceeds the turn-on threshold.

17. The apparatus of claim 16, wherein the voltage drop across the laser diode reduces a voltage appearing at the driver pin of the laser driver.

18. The apparatus of claim 11, wherein the driver pin comprises a current digital-to-analog converter pin.

19. The apparatus of claim 11, wherein the supply voltage is provided by the voltage regulator to the laser diode through a resistance associated with a laser supply line, wherein a voltage drop across the resistance reduces a voltage appearing at the driver pin of the laser driver.

20. The apparatus of claim 19, wherein a resistive voltage drop across the resistance is approximately zero when the current flowing through the laser diode is approximately zero.
